(19) United States
(12) Patent Application Publication
(10) Pub. No.: US 2011/0193186 A1
(43) Pub. Date: Aug. 11, 2011

(54) RADIATION DETECTOR MODULE

(75) Inventors: Juhyun YU, Mito (JP); Naoyuki YAMADA, Hitachinaka (JP); Shinichi INOUE, Ryugasaki (JP); Yoshinori SUNAGA, Hitachinaka (JP); Isao TAKAHASHI, Hitachi (JP)

(73) Assignee: HITACHI CABLE, LTD., Tokyo (JP)

(21) Appl. No.: 12/842,230

(22) Filed: Jul. 23, 2010

(30) Foreign Application Priority Data
Feb. 8, 2010 (JP) 2010-025708

(51) Int. Cl. H01L 31/115

(52) U.S. Cl. 257/429; 257/E31.092

(57) ABSTRACT

A radiation detector module includes a radiation detecting substrate including a plurality of semiconductor devices mounted thereon for detecting radiation, a shielding material at a position nearer to an incident side of the radiation than the radiation detecting substrate, the shielding material being capable of shielding a portion of the radiation, and a fixing member including a bottom, a first side wall extending in a normal direction to the bottom from one end of the bottom, and a second side wall extending in the normal direction to the bottom from an other end of the bottom. The first side wall and the second side wall each include a substrate supporting portion for supporting the radiation detecting substrate, and a shielding material supporting portion at a predetermined position relative to the substrate supporting portion for supporting the shielding material.

The present application is based on Japanese patent application No. 2010-025708 filed on Feb. 8, 2010, the entire contents of which are incorporated herein by reference.

### BACKGROUND OF THE INVENTION

1. Field of the Invention

The present invention relates to a radiation detector module and, in particular, to a radiation detector module that can apply to a portable radiation detector.

2. Description of the Related Art

Conventionally, a gamma ray source distance measuring device is known that is equipped with a multilayer radioactive radiation detector having a plurality of detecting plates disposed in a normal direction for detecting incident radioactive rays, electric charge collecting means provided for the plural detecting plates respectively for collecting electric charges produced for each detecting plate, incidence number detecting means for counting the electric charges for each detecting plate collected by each electric charge collecting means and thereby detecting the number of incident radioactive rays for each detecting plate, and a distance computing means for computing a distance to the radioactive ray source based on the number of incident radioactive rays for each detecting plate and each distance between the adjacent detecting plates of the plural detecting plates (See, e.g., JP-A-2003-315465).

The gamma ray source distance measuring device as disclosed in JP-A-2003-315465 allows the high precision measurement of a direction in which the radioactive ray source exists, or the distance to the radioactive ray source.

Because of computing the distance to the radioactive ray source based on the number of incident radioactive rays for each detecting plate and each distance between the adjacent detecting plates of the plural detecting plates, the gamma ray source distance measuring device as disclosed in IP-A-2003-315465 may however be unable to properly measure the distance to the radioactive ray source as the distance measuring device is downsized.

### SUMMARY OF THE INVENTION

Accordingly, it is an object of the present invention to provide a radiation detector module that can accurately specify the direction of a radiation source.

(1) According to an embodiment of the invention, a radiation detector module comprises:

a radiation detecting substrate comprising a plurality of semiconductor devices mounted thereon for detecting radiation;

a shielding material at a position nearer to an incident side of the radiation than the radiation detecting substrate, the shielding material being capable of shielding a portion of the radiation; and

a fixing member comprising a bottom, a first side wall extending in a normal direction to the bottom from one end of the bottom, and a second side wall extending in the normal direction to the bottom from an other end of the bottom,

wherein the first side wall and the second side wall each comprise a substrate supporting portion for supporting the radiation detecting substrate, and a shielding material supporting portion for supporting the shielding material at a predetermined position relative to the substrate supporting portion.

In the above embodiment (1) of the invention, the following modifications and changes can be made.

(i) The radiation detecting substrate comprises a first radiation detecting substrate with a plurality of semiconductor devices mounted thereon, and a second radiation detecting substrate with a plurality of semiconductor devices mounted thereon, the second radiation detecting substrate being disposed farther from the incident side of the radiation than the first radiation detecting substrate, and

the second radiation detecting substrate comprises a semiconductor device in top view smaller than a semiconductor device mounted on the first radiation detecting substrate.

(ii) The substrate supporting portion supports a part near an edge of the radiation detecting substrate,

the shielding material comprises a columnar shape including a first flat surface, and

the shielding material supporting portion includes a second flat surface contacting the first flat surface of the shielding material, the shielding material being supported by the second flat surface.

(iii) The plurality of semiconductor devices include a first semiconductor device for detecting first energy, and a second semiconductor device for detecting second energy higher than the first energy, and

the first radiation detecting substrate comprises the first semiconductor device on the incident side of the radiation.

(iv) The shielding material comprises lead or tungsten, and

the fixing member comprises a material to transmit more radiation than the shielding material.

(v) The fixing member comprises a resin or metal material.

Points of the Invention

According to one embodiment of the invention, a radiation detector module is constructed such that a portion of incident radiation is shielded by a shielding material formed of a material with a good radiation shielding property, so as to form a region on the radiation detecting substrates being not penetrated by that radiation (i.e. a shadow of that radiation). By semiconductor devices positioned in the shade of the shielding material, no radiation is detected. Therefore, the direction of a radiation source can be accurately specified based on a light receiving count ratio of semiconductor devices with radiation detected and semiconductor devices without radiation detected, and an incident angle of that radiation.

### BRIEF DESCRIPTION OF THE DRAWINGS

The preferred embodiments according to the invention will be explained below referring to the drawings, wherein:

FIG. 1 is a schematic view showing a radiation detector with a built-in radiation detector module in an embodiment according to the invention;

FIG. 2A is a perspective view showing a radiation detector module in the embodiment according to the invention;

FIG. 2B is a perspective view showing the radiation detector module of FIG. 2A, from which circuit substrates have been removed, in the embodiment according to the invention;

FIG. 3A is a perspective view showing a radiation detecting substrate included in the radiation detector module in the embodiment according to the invention;

FIG. 3B is a side view showing the radiation detecting substrate of FIG. 3A included in the radiation detector module in the embodiment according to the invention;

FIG. 3C is a perspective view showing the radiation detecting substrate of FIG. 3A included in the radiation detector module, from which flexible substrates have been removed, in the embodiment according to the invention;

FIG. 3D is a plan view showing one side of the radiation detecting substrate of FIG. 3A included in the radiation detector module, from which flexible substrates have been removed, in the embodiment according to the invention;

FIG. 3E is a plan view showing the other side of the radiation detecting substrate of FIG. 3A included in the radiation detector module, from which flexible substrates have been removed, in the embodiment according to the invention;

FIG. 3F is a perspective view showing a radiation detecting substrate included in the radiation detector module, from which flexible substrates have been removed, in the embodiment according to the invention;

FIG. 3G is a side view showing the radiation detecting substrate of FIG. 3F included in the radiation detector module, from which flexible substrates have been removed, in the embodiment according to the invention;

FIG. 4A is a perspective view showing a fixing member for the radiation detector module in the embodiment according to the invention;

FIG. 4B is a side view showing a fixing member for the radiation detector module in the embodiment according to the invention;

FIG. 5 is a schematic view showing a side surface of the radiation detector module in the embodiment according to the invention; and

FIG. 6 is a schematic view showing the angle resolution of the radiation detector module in the embodiment according to the invention.

### DETAILED DESCRIPTION OF THE PREFERRED EMBODIMENTS

Summary of the Embodiment

According to one embodiment of the invention, a radiation detector module has plural semiconductor devices capable of detecting radiation, and is used to specifying the direction of a radiation source. The radiation detector module is comprised of a radiation detecting substrate with the plural semiconductor devices mounted thereon, a shielding material provided at a position nearer to the incident radiation side than the radiation detecting substrate and capable of shielding a portion of the radiation, and a fixing member having a bottom, a first side wall extending in a normal direction to the bottom from one end of the bottom, and a second side wall extending in the normal direction to the bottom from the other end of the bottom, the first side wall and the second side wall each having a substrate supporting portion for supporting the radiation detecting substrate, and a shielding material supporting portion for supporting the shielding material provided at a predetermined position relative to the substrate supporting portion.

### Embodiment

Radiation Detector 2

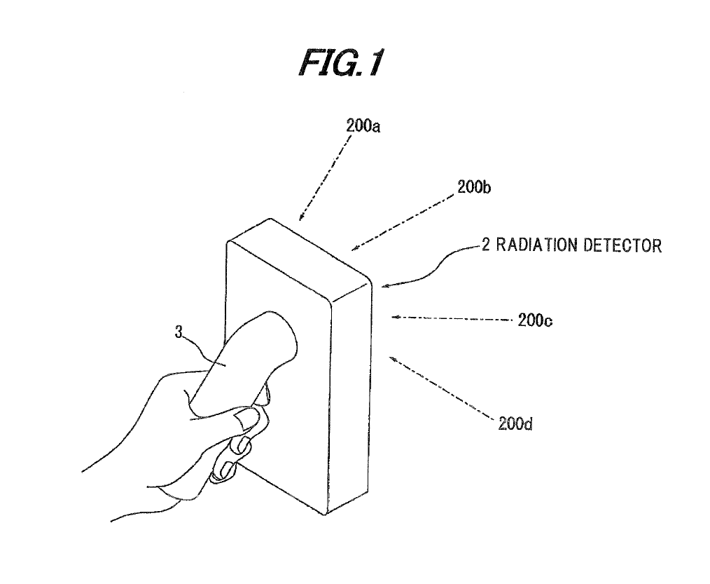

FIG. 1 shows one example of a radiation detector with a built-in radiation detector module in an embodiment according to the invention.

A radiation detector 2 with a built-in radiation detector module 1 in the embodiment of the invention is handy, and capable of probing nuclear materials. Specifically, the radiation detector 2 includes the radiation detector module 1 for detecting radiation 200a to 200d such as gamma rays, X-rays and the like, a data processing unit for processing the detected results of the radiation detector module 1, a communication unit for transmitting the processed results of the data processing unit to an external communication terminal or the like, and a power supply unit for supplying electric power to the data processing unit, etc. The radiation detector 2 is capable of identifying a direction of a radiation source for the radiation 200a to 200d such as gamma rays, X-rays and the like. Also, the radiation detector 2 has as small sized a shape as easy to carry. For example, the radiation detector 2 may be provided with a grip 3 and formed in such an easy to carry shape as a substantially rectangular parallelepiped shape (see, for example, FIG. 1), a flashlight-like cylindrical shape (not shown), or the like.

Radiation Detector Module 1 Construction

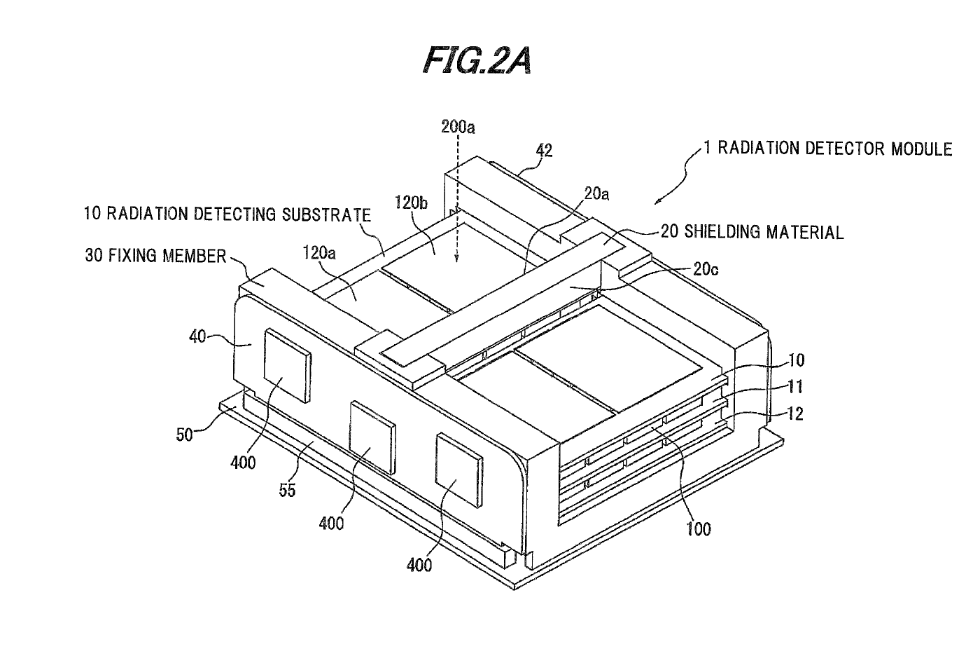

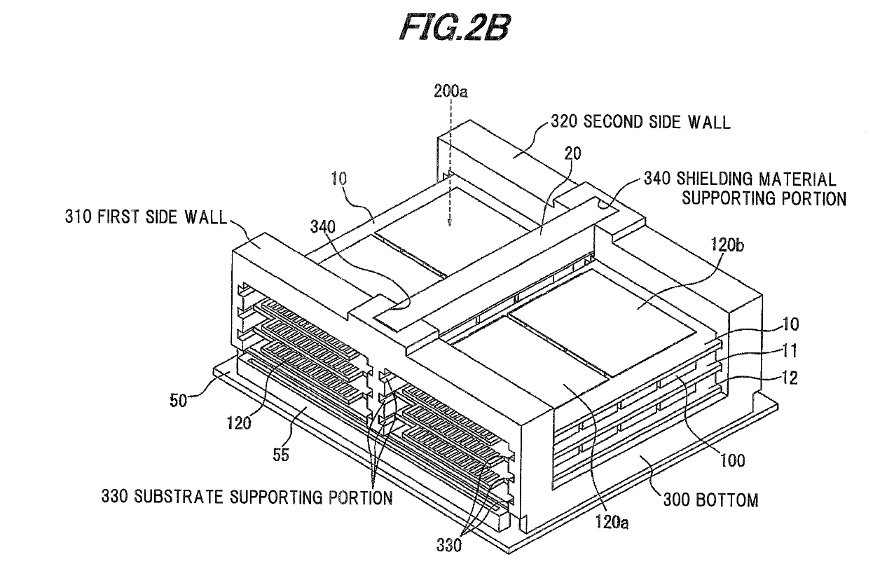

FIG. 2A shows one example of a perspective view showing a radiation detector module in the embodiment according to the invention. Further, FIG. 2B shows one example of a perspective view showing the radiation detector module of FIG. 2A, from which circuit substrates have been removed, in the embodiment according to the invention.

The radiation detector module 1 in the embodiment of the invention includes a plurality of radiation detecting substrates (e.g. radiation detecting substrates 10, 11, and 12) each having a plurality of semiconductor devices (e.g. semiconductor devices 100) mounted thereon and capable of detecting radiation, a shielding material 20 capable of shielding a portion of the radiation (e.g. radiation 200a) incident on the radiation detector module 1, and a fixing member 30 for holding at least a peripheral portion of each of the plural radiation detecting substrates, and fixing the shielding material 20 at a predetermined position relative to the plural radiation detecting substrates. The number of radiation detecting substrates is not limited to the above, but may be one or more. In this case, the fixing member 30 is formed according to the number of radiation detecting substrates to be provided in the radiation detector module 1, so that it may hold all the radiation detecting substrates.

Also, the radiation detector module 1 in this embodiment is further provided with first and second circuit substrates 40 and 42 each having a plurality of integrated circuits 400 mounted thereon. Each of edge portions 120 at one end and the other end of each of the plural radiation detecting substrates is electrically connected to the first and second circuit substrates 40 and 42, respectively. The plural radiation detecting substrates each are sandwiched between the circuit substrates 40 and 42. Further, the radiation detector module 1 is provided with a motherboard 50 having a connector 55 into which is inserted the circuit substrate 40, and a connector (not shown) into which is inserted the circuit substrate 42. The connector 55 is provided at one end of the motherboard 50, while the connector into which is inserted the circuit substrate 42 is provided at the opposite end of the motherboard 50.

That is, the radiation detector module 1 is constructed as follows: the fixing member 30 is mounted on the surface of the motherboard 50, the plural radiation detecting substrates and the shielding material 20 are fixed to the fixing member 30, and the circuit substrates 40 and 42, which are connected to each of the plural radiation detecting substrates, are fixed to the motherboard 50. The radiation detector module 1 may further be provided with a case for storing the plural radiation detecting substrates, the shielding material 20, the fixing member 30, the circuit substrates 40 and 42, and the motherboard 50.

Also, the fixing member 30 is formed to have a bottom 300, a first side wall 310 extending in a normal direction to the bottom 300 from one end of the bottom 300, and a second side wall 320 extending in the normal direction (the same direction as the extending direction of the first side wall 310) to the bottom 300 from the other end of the bottom 300 (see FIG. 2B). The first side wall 310 and the second side wall 320 each have a substrate supporting portion 330 for supporting each of the plural radiation detecting substrates, and a shielding material supporting portion 340 for supporting the shielding material 20 provided at a predetermined position relative to the substrate supporting portion 330. This detail will be described later.

Shielding Material 20

The shielding material 20 is provided at a position nearer to the incident radiation side than the radiation detecting substrates (e.g. radiation detecting substrates 10, 11, and 12). For example, the shielding material 20 is provided at a position excluding directly above the plural semiconductor devices (e.g. semiconductor devices 100). Also, the shielding material 20 is formed to have a columnar shape including a flat surface. The shielding material 20 is formed to contain a material capable of shielding radiation, such as lead or tungsten.

Radiation Detecting Substrate 10

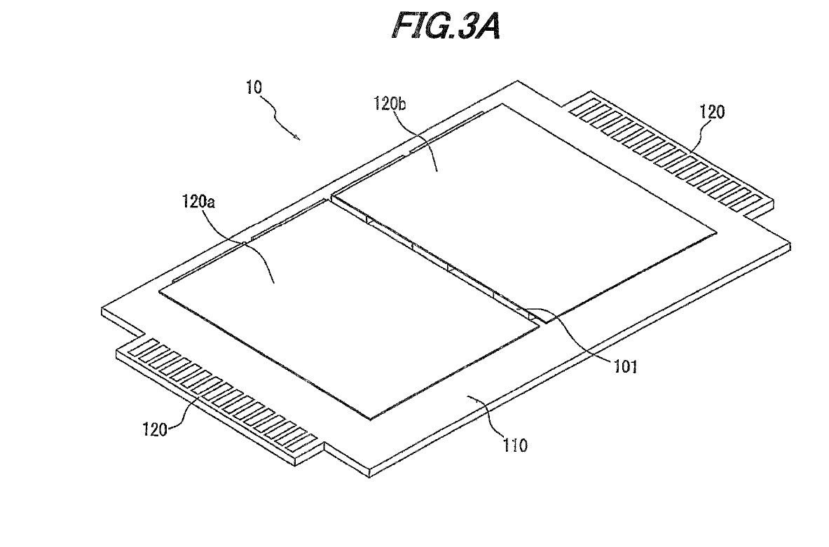

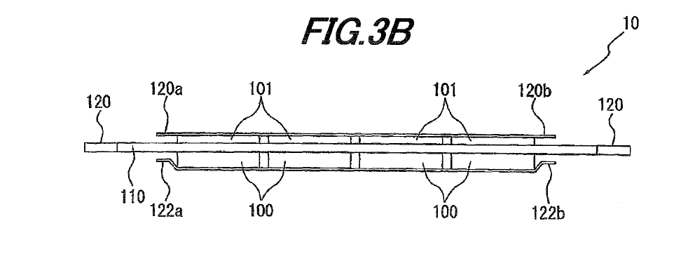

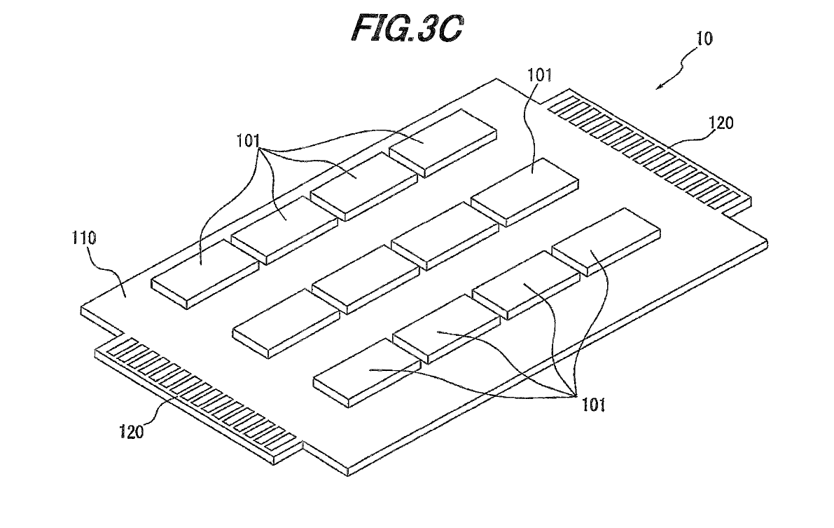

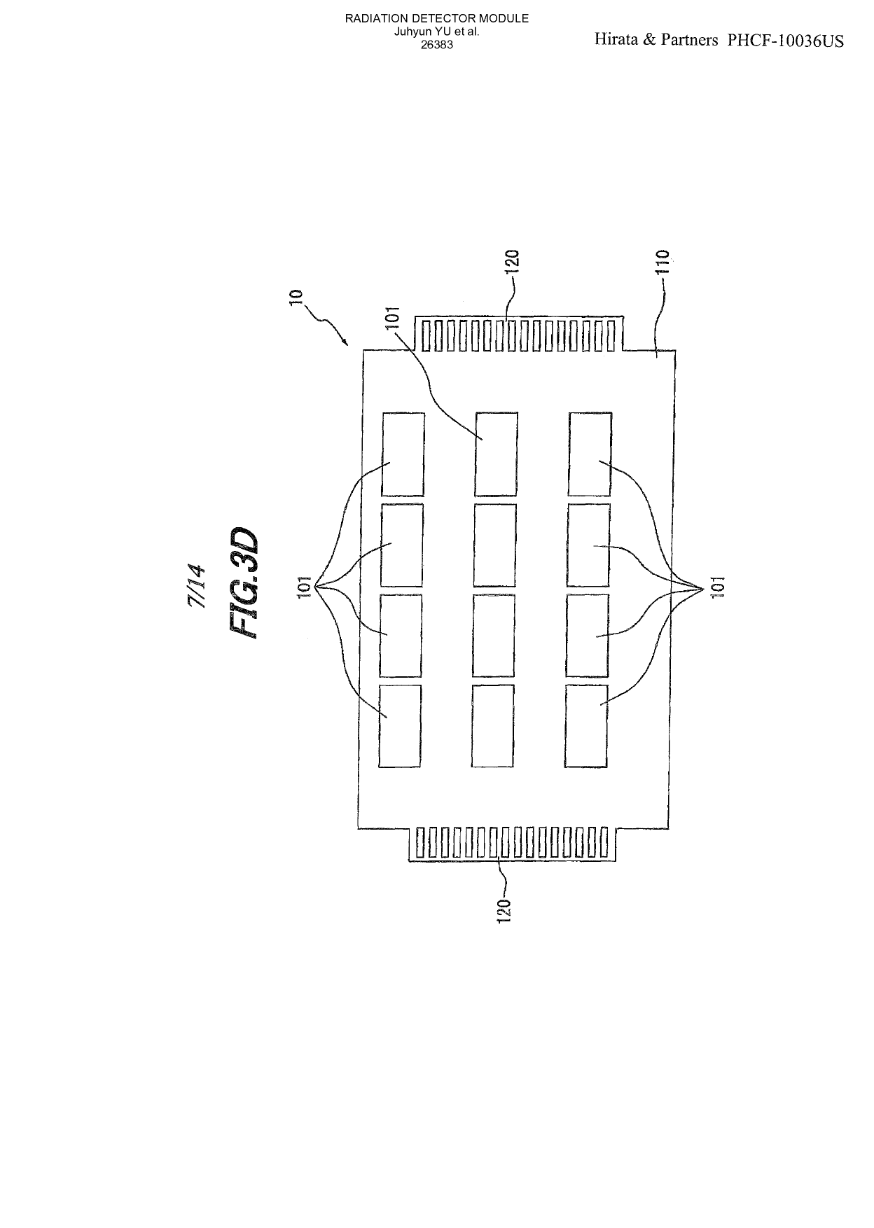

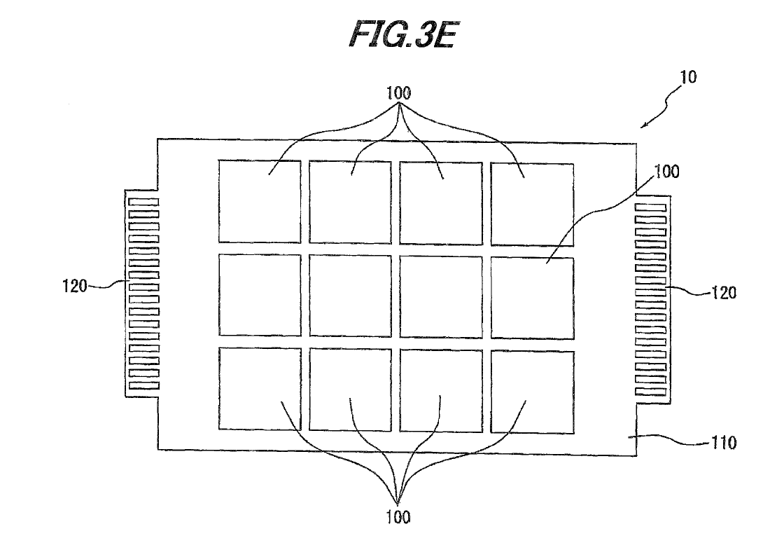

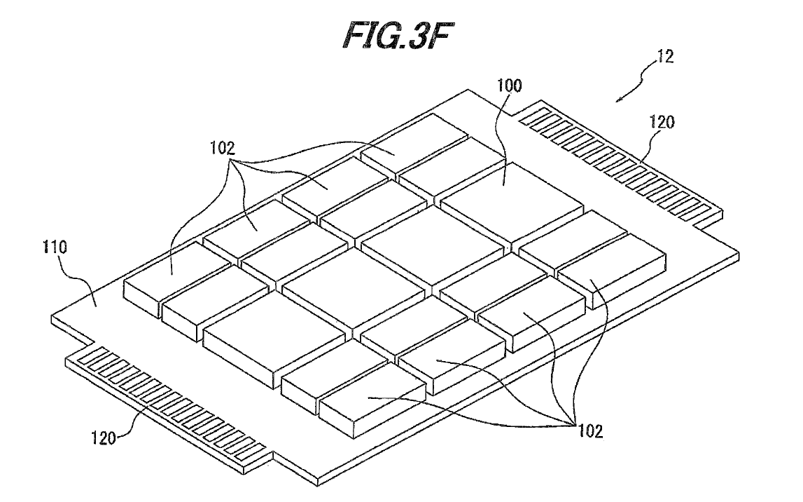

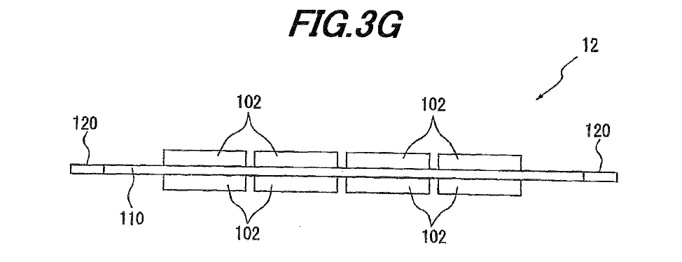

FIG. 3A shows one example of a perspective view showing a radiation detecting substrate included in the radiation detector module in the embodiment according to the invention, and FIG. 3B shows one example of a side view showing the radiation detecting substrate included in the radiation detector module in the embodiment according to the invention.

The radiation detecting substrate 10 (herein, also referred to as the first radiation detecting substrate) is constructed of a glass epoxy substrate or the like, and provided with a rigid substrate 110 which is substantially rectangular in a plan view, edges 120 formed at both ends (e.g. both short side ends) of the rigid substrate 110, a plurality of semiconductor devices 101 mounted on one surface of the rigid substrate 110 as first semiconductor devices for detecting first energy, and a plurality of semiconductor devices 100 mounted on the other surface of the rigid substrate 110 as second semiconductor devices for detecting second energy higher than the first energy. Here, the plural semiconductor devices 101 are provided on the incident radiation side relative to the semiconductor devices 100. The number of semiconductor devices 100 and 101 to be provided for the radiation detecting substrate 10 may appropriately be altered according to use of the radiation detector module 1. Also, the semiconductor devices to be mounted on one surface and the other surface of the rigid substrate 110 may be the same semiconductor devices.

Also, the radiation detecting substrate 10 is provided with a flexible substrate 120a including a wiring pattern to be electrically connected to the plural semiconductor devices 101 at one edge 120, and a flexible substrate 120b including a wiring pattern to be electrically connected to the plural semiconductor devices 101 at the other edge 120, and the flexible substrates 120a and 120b being not electrically connected with each other. Likewise, the radiation detecting substrate 10 is provided with a flexible substrate 122a including a wiring pattern to be electrically connected to the plural semiconductor devices 100 at one edge 120, and a flexible substrate 122b including a wiring pattern to be electrically connected to the plural semiconductor devices 100 at the other edge 120, and the flexible substrates 122a and 122b being not electrically connected with each other. The flexible substrates 120a and 122a are each electrically connected to the circuit substrate 40, while the flexible substrates 120b and 122b are each electrically connected to the circuit substrate 42.

Here, the semiconductor devices 100 and 101 may use CdTe devices, CdZnTe (CZT) devices, HgI₂ devices, etc. Also, the semiconductor devices 100 and 101 may each be formed by use of the same or different materials. Further, the semiconductor devices 100 and 101 may be formed in a rectangular or square shape in a plan view. As one example, the thickness of the semiconductor devices may then be varied, to thereby adjust a detectable radiation energy band. In this case, it is preferred to dispose the lower energy radiation detecting semiconductor devices nearer to the incident radiation side.

FIG. 3C shows one example of a perspective view showing the radiation detecting substrate included in the radiation detector module, from which flexible substrates have been removed, in the embodiment according to the invention. Also, FIG. 3D shows one example of a plan view showing one side of the radiation detecting substrate included in the radiation detector module, from which flexible substrates have been removed, in the embodiment according to the invention, and FIG. 3E shows one example of a plan view showing the other side of the radiation detecting substrate included in the radiation detector module, from which flexible substrates have been removed, in the embodiment according to the invention.

As shown in FIGS. 3C and 3D, the plural semiconductor devices 101 are arranged in a lattice farm in a plan view on one surface of the rigid substrate 110. That is, the plural semiconductor devices 101 are spaced at a predetermined pitch in each of the longitudinal and transverse directions on one surface of the rigid substrate 110. Also, as shown in FIG. 3E, the plural semiconductor devices 100 are likewise spaced at a predetermined pitch in each of the longitudinal and transverse directions on the other surface of the rigid substrate 110.

Radiation Detecting Substrate 11 and/or 12

FIG. 3F shows one example of a perspective view showing a radiation detecting substrate included in the radiation detector module, from which flexible substrates have been removed, in the embodiment according to the invention, and FIG. 3G shows one example of a side view showing the radiation detecting substrate included in the radiation detector module, from which flexible substrates have been removed, in the embodiment according to the invention.

The radiation detecting substrate 11 and/or 12 (herein, also referred to as the second radiation detecting substrates) is disposed farther from the incident radiation side than the first radiation detecting substrate 10. For example, as having been shown in FIG. 2B, the radiation detecting substrates 10, 11 and 12 are arranged in this order from the incident radiation side. The radiation detecting substrate 11 and/or 12 is then provided with a plurality of semiconductor devices (e.g. semiconductor devices 102) smaller sized in a plan view than the semiconductor devices mounted on the radiation detecting substrate 10 (e.g. semiconductor devices 100).

In FIGS. 3F and 3G, one example for the radiation detecting substrate 12 is shown. The radiation detecting substrate 12 has substantially the same structure as the radiation detecting substrate 10, except the size of the semiconductor devices to be mounted on the radiation detecting substrate 12 being different from the size of the semiconductor devices mounted on the radiation detecting substrate 10.

Specifically, the radiation detecting substrate 12 is provided with the semiconductor devices 102 smaller sized in a plan view than the semiconductor devices 100 mounted on the radiation detecting substrate 10. That is, when the first radiation detecting substrate (e.g. radiation detecting substrate 10) is arranged at a first position, and the second radiation detecting substrate (e.g. radiation detecting substrate 12) is arranged at a second position farther from the incident radiation side than the first position, the second radiation detecting substrate 12 is provided with the semiconductor devices smaller sized in a plan view than the semiconductor devices provided for the first radiation detecting substrate 10 arranged at the first position, i.e. the semiconductor devices with a transverse width narrower than that of the semiconductor devices provided for the first radiation detecting substrate 10 arranged at the first position. As for the second radiation detecting substrate 12, at least a portion of the semiconductor devices mounted on the second radiation detecting substrate 12 may be the semiconductor devices smaller sized in a plane view than the semiconductor devices provided for the first radiation detecting substrate 10 arranged at the first position.

Fixing Member 30

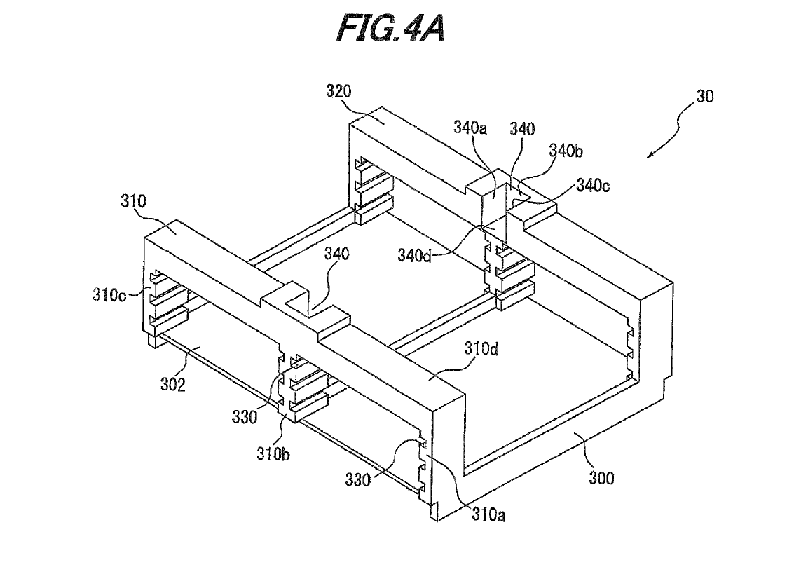

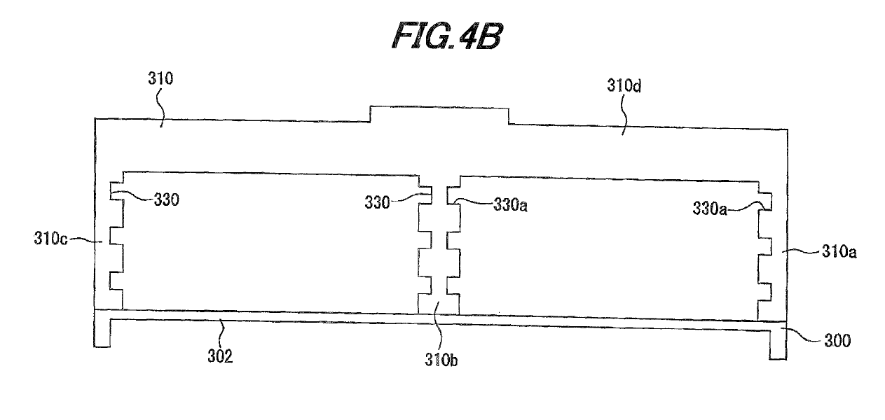

FIG. 4A shows one example of a perspective view showing a fixing member for the radiation detector module in the embodiment according to the invention, and FIG. 4B shows one example of a side view showing a fixing member for the radiation detector module in the embodiment according to the invention.

The fixing member 30 is formed to have a bottom 300 including a bottom plate 302, a first side wall 310, and a second side wall 320. The first side wall 310 and the second side wall 320 each then have a substrate supporting portion 330 for supporting each of the plural radiation detecting substrates, and a shielding material supporting portion 340 for supporting the shielding material 20. Here, the bottom 300, the first side wall 310, and the second side wall 320 may be formed to have an integral structure.

The fixing member 30 may be formed by use of a material which transmits more radiation than the shielding material 20. Specifically, it may be formed by injection molding or cutting work with good accuracy in dimensions, using a resin material such as polyphenylene sulfide resin (PPS), polyimide resin (PI), polyacetal resin (POM) or the like. Also, the fixing member 30 may be formed of a metal material such as aluminum, stainless steel or the like. When the fixing member 30 is formed of a resin, it is preferred that it is formed of PPS, in order to ensure the position accuracy of the plural radiation detecting substrates relative to the shielding material 20, and to ensure the mechanical strength of the fixing member 30.

The first side wall 310 and the second side wall 320 have mutually substantially the same structure and function, except that they are provided at one end or the other end, respectively, of the bottom 300. Herein is therefore described the first side wall 310. For the shielding material supporting portion 340, it should be noted, however, that, for convenience of description, there is described the shielding material supporting portion 340 provided for the second side wall 320.

The first side wall 310 includes a pillar 310a extending in a normal direction to the bottom plate 302 from one corner of the bottom plate 302, a beam 310d extending along the width of the bottom plate 302 including that one corner at its end, to interconnect with the tip of the pillar 310a, a pillar 310c extending to the bottom plate 302 from the other end of the beam 310d opposite one end of the beam 310d interconnecting with the pillar 310a, to interconnect with the bottom plate 302, and an intermediate portion 310b between the pillars 310a and 310c, extending from a middle region of the beam 310d to the surface of the bottom plate 302.

The substrate supporting portion 330 is defined as a plurality of grooves in each of an intermediate portion 310b side surface of the pillar 310a, an intermediate portion 310b side surface of the pillar 310c, and pillar 310a and 310c side surfaces of the intermediate portion 310b. The substrate supporting portion 330 is then formed to include a flat supporting surface 330a along the outer surface of the radiation detecting substrate. As one example, the supporting surface 330a is formed to be parallel to the surface of the bottom plate 302.

The shielding material supporting portion 340 is provided on the opposite side of the beam 310d relative to the intermediate portion 310b side. The shielding material supporting portion 340 is formed to include a horizontal surface 340d relative to the bottom plate 302, and vertical surfaces 340a, 340b, and 340c relative to the horizontal surface 340d. The surfaces 340a and 340c are provided to be positioned opposite each other, and the surface 340b is provided to be perpendicular to the surfaces 340a and 340c.

Side Surface of the Radiation Detector Module 1

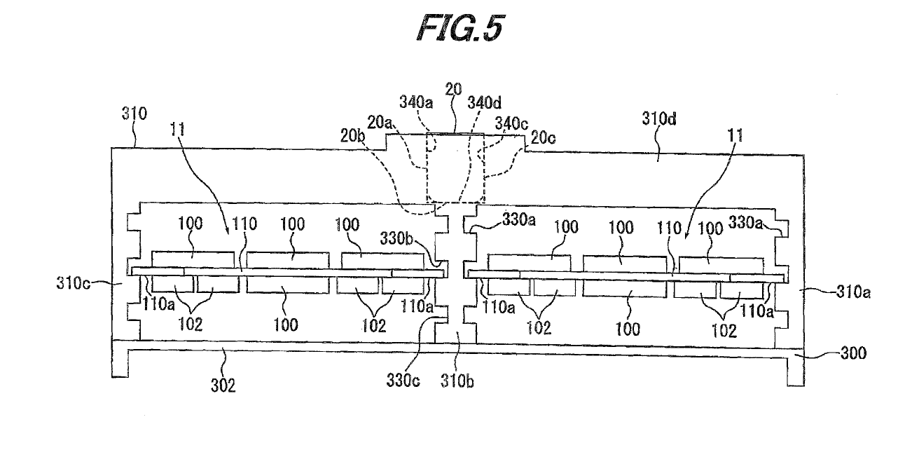

FIG. 5 is a schematic view showing a side surface of the radiation detector module 1 in the embodiment according to the invention.

In FIG. 5, for convenience of description, the circuit substrate 40, the radiation detecting substrate 10, the radiation detecting substrate 12, and the flexible substrates provided for the radiation detecting substrate 11 are omitted and not illustrated.

First, the substrate supporting portions 330 are each formed in a recessed shape when viewed from a side surface of the fixing member 30. That is, each substrate supporting portion 330 includes the supporting surface 330a, a supporting surface 330b opposite the supporting surface 330a, and a side portion 330c being perpendicular to and interconnecting with the supporting surfaces 330a and 330b. The substrate supporting portions 330 then support an adjacent edge of the radiation detecting substrate 11. Specifically, when the radiation detecting substrate 11 is inserted into the substrate supporting portions 330, a substrate surface 110a of the radiation detecting substrate 11 is contacted with the supporting surface 330a, thereby the radiation detecting substrate 11 being supported by the substrate supporting portions 330. One substrate supporting portion 330 is set to have a distance between its supporting surfaces 330a and 330b of not less than the thickness of the radiation detecting substrate 11.

Also, the shielding material supporting portion 340 is contacted with a flat surface 20a of the shielding material 20 at its surface 340a, a flat surface 20c of the shielding material 20 at its surface 340c, and a flat surface 20b of the shielding material 20 at its surface 340d, thereby supporting the shielding material 20. That is, the respective positions of the surfaces 340a, 340c and 340d of the shielding material supporting portion 340 are controlled relative to the fixing member 30, thereby allowing the shielding material 20 to be controlled at a precise position relative to the fixing member 30, and supported by the shielding material supporting portion 340.

Angle Resolution of the Radiation Detector Module 1

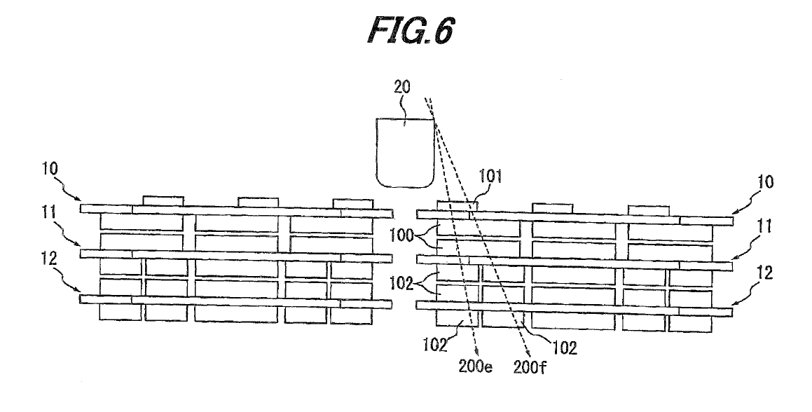

FIG. 6 is a schematic view showing the angle resolution of the radiation detector module 1 in the embodiment according to the invention.

In FIG. 6, for convenience of description, the fixing member 30, the circuit substrate 40, the circuit substrate 42, each flexible substrate, etc. are omitted and not illustrated.

The shielding material 20 is for shielding radiation from outside. Accordingly, at semiconductor devices positioned in the shade of the shielding material 20, no radiation is detected. This therefore allows a direction of a radiation source to be specified from a radiation receiving count ratio of semiconductor devices having detected radiation and semiconductor devices having detected no radiation, and an incident angle of that radiation.

Here, in this embodiment, the semiconductor devices 102 disposed far from the incident radiation side are smaller sized in a plan view than the semiconductor devices 100 disposed near to the incident radiation side. This allows the enhancement of the incident angle resolution of radiation incident on the radiation detector module 1. As shown in FIG. 6, in this embodiment, the plural radiation detecting substrates 10 to 12 are stacked at a specified pitch. This results in a stacked structure of the semiconductor devices 100 to 102 in a plan view. It is therefore possible to facilitate the computing of a scattered radiation angle, and the acquisition of data required for the scattered radiation computing.

Effects of the Embodiment

The radiation detector module 1 in this embodiment is constructed such that a portion of incident radiation is shielded by the shielding material 20 formed of a material having a good radiation shielding property, thereby allowing the formation of a region on the radiation detecting substrates being not penetrated by that radiation (i.e. a shadow of that radiation). It is therefore possible to make the design of a small sized radiation detector module easier than the conventional art.

Also, the radiation detector module 1 is constructed such that the plural radiation detecting substrates 10 to 12 and the shielding material 20 are supported by the fixing member 30 formed of a resin or metal material having a poorer radiation shielding property than the shielding material 20. It is therefore possible to inhibit the fixing member 30 from shielding radiation, and thereby enhance the angle resolution and ensure a large viewing angle.

Further, the radiation detector module 1 is constructed such that the fixing member 30 is formed of a resin or metal material to be easily subjected to precision work. It is therefore possible to control the plural radiation detecting substrates 10 to 12 at a precise position relative to the shielding material 20. This makes it possible to easily enhance the angle resolution of the radiation detector module 1.

Although the invention has been described with respect to the above embodiments, the above embodiments are not intended to limit the appended claims. Also, it should be noted that not all the combinations of the features described in the above embodiments are essential to the means for solving the problems of the invention.

What is claimed is:

1. A radiation detector module, comprising:
a radiation detecting substrate comprising a plurality of semiconductor devices mounted thereon for detecting radiation;
a shielding material at a position nearer to an incident side of the radiation than the radiation detecting substrate, the shielding material being capable of shielding a portion of the radiation; and
a fixing member comprising a bottom, a first side wall extending in a normal direction to the bottom from one end of the bottom, and a second side wall extending in the normal direction to the bottom from an other end of the bottom,
wherein the first side wall and the second side wall each comprise a substrate supporting portion for supporting the radiation detecting substrate, and a shielding material supporting portion for supporting the shielding material at a predetermined position relative to the substrate supporting portion.

2. The radiation detector module according to claim 1, wherein
the radiation detecting substrate comprises a first radiation detecting substrate with a plurality of semiconductor devices mounted thereon, and a second radiation detecting substrate with a plurality of semiconductor devices mounted thereon, the second radiation detecting substrate being disposed farther from the incident side of the radiation than the first radiation detecting substrate, and
the second radiation detecting substrate comprises a semiconductor device in top view smaller than a semiconductor device mounted on the first radiation detecting substrate.

3. The radiation detector module according to claim 2, wherein
the substrate supporting portion supports a part near an edge of the radiation detecting substrate,
the shielding material comprises a columnar shape including a first flat surface, and
the shielding material supporting portion includes a second flat surface contacting the first flat surface of the shielding material, the shielding material being supported by the second flat surface.

4. The radiation detector module according to claim 3, wherein
the plurality of semiconductor devices include a first semiconductor device for detecting first energy, and a second semiconductor device for detecting second energy higher than the first energy, and
the first radiation detecting substrate comprises the first semiconductor device on the incident side of the radiation.

5. The radiation detector module according to claim 4, wherein
the shielding material comprises lead or tungsten, and
the fixing member comprises a material to transmit more radiation than the shielding material.

6. The radiation detector module according to claim 5, wherein
the fixing member comprises a resin or metal material.
